(19) United States
(12) Patent Application Publication
(10) Pub. No.: US 2023/0361151 A1
(43) Pub. Date: Nov. 9, 2023

(54) METHOD FOR MANUFACTURING MICROLENSES

(71) Applicant: STMicroelectronics (Crolles 2) SAS, Crolles (FR)

(72) Inventors: Jonathan Fantuz, Vaulnaveys Le Haut (FR); Alain Inard, St Nazaire Les Eymes (FR); Didier Dutartre, Meylan (FR)

(21) Appl. No.: 18/298,781

(22) Filed: Apr. 11, 2023

(30) Foreign Application Priority Data
May 5, 2022 (FR) 2204255

(51) Int. Cl. H01L 27/146

(52) U.S. Cl. CPC H01L 27/14685; H01L 27/14627

(57) ABSTRACT

In accordance with an embodiment, a method for manufacturing an optical device on a support substrate includes: forming first microlens structures on the support substrate using a first photolithography process such that the first microlens structures are separated from one another; deforming the first microlens structures so as to give the first microlens structures a curved shape, wherein the first microlens structures are separated from one another by spacer regions after deformation; forming second microlens structures substrate using a second photolithography process such that the second microlens structures extend over the first microlens structures; and deforming the second microlens structures such that the second microlens structures have a curved form matching the curved shape of the first microlens structures and extend partly into the spacer regions between the first microlens structures.

### CROSS-REFERENCE TO RELATED APPLICATIONS

This application claims the benefit of French Patent Application No. 2204255, filed on May 5, 2022, which application is hereby incorporated herein by reference.

### TECHNICAL FIELD

Embodiments and implementations relate to microlenses and methods for manufacturing microlenses.

### BACKGROUND

An optical sensor is a device for detecting light intensity and transforming it into a measurable quantity such as current or voltage. An optical sensor generally comprises an array of photosensitive areas and microlenses. In particular, each photosensitive area is covered with a microlens and is configured to generate a current from incident photons. The photons can be used for example for reconstituting an image when they are collected by the optical sensor. Each pixel of the image corresponds to photons absorbed by a photosensitive area of the array.

Microlenses are lenses which generally have a diameter of less than 100 μm. The diameter can extend down to dimensions in the order of μm, more typically between 1 and 10 μm.

A microlens makes it possible to focus the light on a photosensitive area over which the microlens is located. A photosensitive area can capture a larger amount of photons by being covered by a microlens, which makes it possible to increase a quantum efficiency of the photosensitive area. The quantum efficiency (QE) corresponds to the ratio between the number of incident photons and the number of photons absorbed by the photosensitive area. This ratio therefore depends on the number of photons coming into contact with the surface of the microlens and redirected to the photosensitive area.

In order to optimize the quantum efficiency, i.e. to obtain a quantum efficiency close to 1, it is desirable to space apart the microlenses as little as possible to collect all of the incident photons and thus reduce the light losses. End-to-end micro-lenses also have the advantage of reducing optical interference by preventing photons from landing on neighboring photosensitive areas.

An example of a known technique for forming microlenses uses simple photolithography. Photolithography makes it possible to reproduce a plurality of microlens structures according to a given pattern by using a mask on a support substrate. The microlens structures have an intermediate parallelepiped form, which is also referred to in the following as a “pad”. Said pads are then distributed over the surface of the substrate and spaced apart from one another. The microlens structures are then subjected to thermal creep, i.e. become liquid from the action of heat in order to allow the wetting of the structures on the substrate. The wetting corresponds to a natural deformation of a liquid in contact with the surface of a solid. A microlens structure in contact with the surface of the substrate then naturally takes on a final curved shape and thus forms a microlens.

During the creep, the pad not only takes on the form of a microlens, but also extends over the substrate such that the microlens obtained covers a larger area of the substrate. When the structures formed by photolithography are too close together the latter are at risk of forming bridges with one another “bridging” and thus connecting together.

A bridge formed between the microlenses corresponds to the fusion between the ends of the microlenses located side by side. A bridge between two microlenses does not allow photons passing through the bridge to be directed properly to the photosensitive areas located under these microlenses.

Furthermore, the photons traversing a bridge are likely to create optical interference between the photosensitive areas of the array. Optical interference occurs for example when the photons are redirected to a different photosensitive area than the one for which they are intended.

This leads to a reduction in the performance of the optical sensor and a loss of information on the image to be reconstructed.

Furthermore, current photolithography techniques do not make it possible to sufficiently reduce the distances between each microlens structure without the risk of bridging between the microlenses and are not sufficiently precise to completely reduce the distance between the microlenses.

In this regard, other standard techniques for manufacturing microlenses make it possible to reduce the spacing between the microlenses without forming bridges.

For example, one method provides a first photolithography process for forming first microlenses so that the first microlenses cover every other photosensitive area. After the cross-linking of the first microlenses, the second microlenses are then formed by a second photolithography process between each first microlens to cover the remaining photosensitive areas. Thus, such a method makes it possible to obtain first microlenses and second microlenses which are not spaced apart or are only spaced apart from one another by a small amount.

However, the alignment of the first microlenses and second microlenses is still relatively complex in this method and each of the photolithography steps requires the use of a different mask, which represents a significant extra cost when manufacturing microlenses.

Another example of a commonly used method for forming microlenses is based on the plasma transfer of microlenses onto an intermediate layer arranged on the substrate. Although the plasma makes it easier to adjust the spacing between the microlenses on the intermediate layer in order to reduce or remove the spacing between the microlenses, radiation emitted by the plasma may cause severe damage to the photosensitive areas of the optical sensor and make the surface of the microlenses rougher.

There is therefore a need to propose a solution that makes it possible to reduce the spacing between the microlenses and increase the quantum efficiency while avoiding high manufacturing costs and avoiding damage to the photosensitive areas of the optical sensor.

### SUMMARY

According to an embodiment, a method is proposed for manufacturing an optical device on a support substrate, comprising forming a plurality of microlenses. The formation of the plurality of microlenses includes forming first microlens structures by photolithography on the support substrate such that the first microlens structures are separated from one another, then by deforming the first microlens structures so as to give the first microlens structures a curved shape, the first microlens structures being separated from one another by spacer regions after deformation.

The formation of the plurality of microlenses also includes forming second microlens structures by photolithography such that the second microlens structures extend over the first microlens structures then deforming the second microlens structures such that the second structures have a curved shape matching the curved shape of the first microlens structures and extend partly into the spacer regions between the first microlens structures.

Each microlens is thus formed by superimposing a first microlens structure and a second microlens structure.

The formation of microlenses by superimposing the second microlens structures onto the first microlens structures makes it possible to reduce the spacing between the microlenses, and eliminate it in order to avoid the formation of bridges between each microlens.

Indeed, the fact of forming the second microlens structures on the first microlens structures makes it possible to more easily control the deformation of the second microlens structures such that the second microlens structures extend into the spacer regions to reduce the spacing between the microlenses.

According to one embodiment, each second microlens structure has, after deformation, a curvature greater than or equal to a curvature of each first microlens structure.

The curvature of each second microlens structure can therefore be adjusted independently of the curvature of each first microlens structure. A higher microlens curvature makes it possible to reduce the focal distance of the microlens to converge the light on the photosensitive area when the latter is close to the microlens.

According to one embodiment, the method further comprises cross-linking of the first microlens structures by heat treatment following their deformation, and cross-linking of the second microlens structures by heat treatment following the deformation of the second structures.

Cross-linking after the deformation of the microlens structures makes it possible to remove the solvents in each of the microlens structures and to solidify the microlens structures in order to maintain their fixed position and stabilize them on the substrate.

According to one embodiment, photolithography processes for forming the microlens structures and the second microlens structures are performed by using the same mask.

The use of a single mask for the two photolithography processes makes it possible to reduce the cost of manufacturing microlenses and perform a second photolithography process more rapidly.

According to one embodiment, the deformation of the second microlens structures comprises a diffusion plasma treatment at a suitable temperature. The second microlens structures are then deformed by creep, allowing the wetting of the second microlens structures on the first microlens structures so as to match the shape of the first microlens structures and extend partially into the spacer regions.

The temperature of the diffusion plasma treatment can be determined according to the nature of the material of the microlens structure to better control the deformation of the second microlens structures and to obtain the desired microlens shape.

The use of a diffusion plasma makes it possible to obtain the deformation of the microlens structures without the risk of damaging and affecting the roughness of the microlenses.

According to one embodiment, the diffusion plasma is a carbon and dioxygen tetrafluoride plasma.

According to one embodiment, the first microlens structures and the second microlens structures are formed by different materials.

According to one embodiment, the first microlens structures and the second microlens structures are each formed by a novolac polymer resin.

According to one embodiment, the second microlens structures are formed by a material selected to limit the reflection of light on the outer surface of second microlens structures.

By limiting the reflection of light on the outer surface of the second microlens structures, a loss of photons is avoided and as a result a reduction in quantum efficiency.

According to one embodiment, the material forming the second microlens structures has a refractive index of between 1.5 and 1.7.

According to one embodiment, the thickness of the second microlens structures is between 400 nm and 4 μm.

Thus, the method also makes it possible to use second microlens structures for smoothing the surface of the first microlens structures that can sometimes be very rough.

According to one embodiment, the thickness of the second microlens structures is greater than 0.1 μm.

Second microlens structures having such a thickness value can be better distributed in the spacer regions between the first microlens structures. In this way, a sufficient thickness is obtained achieved for reducing, or removing, the spacing between the microlenses.

According to one embodiment, the first microlens structures are formed to be spaced apart from one another by a distance greater than or equal to 300 nm.

A minimum spacing between the first microlens structures makes it possible to reduce, or avoid, the formation for bridges between the first microlens structures.

According to one embodiment, the second microlens structures are formed by photolithography to be spaced apart from one another, before the deformation, by a distance greater than or equal to 300 nm.

According to one embodiment, the second microlens structures are spaced apart from one another, after the deformation of the second microlens structures by a distance of at least essentially zero.

According to another aspect, a semiconductor device is proposed comprising a support substrate and a plurality of microlenses.

The plurality of microlenses includes first microlens structures with a curved shaped arranged on the support substrate such that the first microlens structures are separate from one another by spacing regions.

The plurality of microlenses also includes second microlens structures extending over the first microlens structures and deformed such that the second structures have a curved shape matching the curved shape of the first microlens structures and extend partly into the spacer regions between the first microlens structures.

According to one embodiment, each second deformed microlens structure has a curvature greater than or equal to a curvature of each first microlens structure.

According to one embodiment, the materials of the first microlens structures and the second microlens structures are different.

According to one embodiment, the first microlens structures and the second microlens structures are made of novolac polymer resin.

According to one embodiment, the material of the second microlens structures is configured to limit the reflection of light on the outer surface of the second microlens structures.

According to one embodiment, the material of the second microlens structures has a refractive index of between 1.5 and 1.7.

According to one embodiment, the thickness of the second microlens structures is between 400 nm and 4 μm.

According to one embodiment, the thickness of the second microlens structures is greater than 0.1 μm.

According to one embodiment, the first microlens structures are spaced apart from one another by a distance greater than or equal to 300 nm.

According to one embodiment, the second microlens structures are spaced apart from one another by a distance of at least essentially zero.

### BRIEF DESCRIPTION OF THE DRAWINGS

Further advantages and features of the invention are given in the detailed description of non-limiting embodiments and implementations and the accompanying drawings in which:

FIG. 1 illustrates a flowchart of a method for manufacturing an optical sensor;

FIGS. 2-9 illustrate cross-sectional views of an embodiment optical sensor at various stages of fabrication; and

FIGS. 10-12 illustrate plan view of the embodiment optical sensor at various stages of fabrication.

### DETAILED DESCRIPTION OF ILLUSTRATIVE EMBODIMENTS

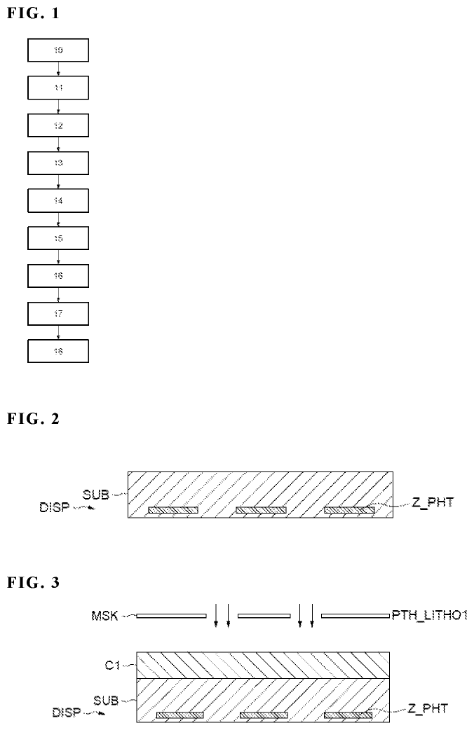

FIG. 1 illustrates schematically a way of implementing a method for manufacturing an optical sensor DISP. The manufacturing method comprises obtaining 10 a support substrate SUB as represented in FIG. 2 in cross-section. The support substrate SUB is made from a material currently use for manufacturing microlenses, such as polysilicon for example, and includes photosensitive zones Z_PHT formed by different types methods known per se as a function of the nature of the photosensitive zone Z_PHT. The photosensitive zone Z_PHT can be a junction photodiode or a buried photodiode for example. The substrate can be p-type or n-type and the substrate can have a higher or lower resistivity. The doping of the transistors will differ depending on the substrate and the type of photodiode.

The method then comprises steps 11 to 18 for forming microlenses on the substrate SUB. The microlenses are not necessarily formed directly on the substrate SUB. In particular, layers, such as layers forming color filters, can be interposed between the substrate SUB and the microlenses.

More particularly, the formation of microlenses includes forming curved first microlens structures by steps 11 to 14 then forming second curved microlenses on the first microlens structures by steps 15 to 18.

The method thus comprises forming 11 a first layer of material C1 on the support substrate SUB. The first layer C1 can be made from photosensitive resin. The photosensitive resin can be made of a novolac polymer (usually referred to as novolacs). For example, the photosensitive resin can be a MFR 400LL resin from the Japanese company JSR Corporation. FIG. 3 illustrates a cross-sectional view of a result that can be obtained as a result of this forming 11.

The method comprises forming 12 first microlens structures LS1 by photolithography PHT_LITO1 on the support substrate SUB such that the first microlens structures LS1 are separated from one another. Each first microlens structure LS1 then has an intermediate pattern of dots.

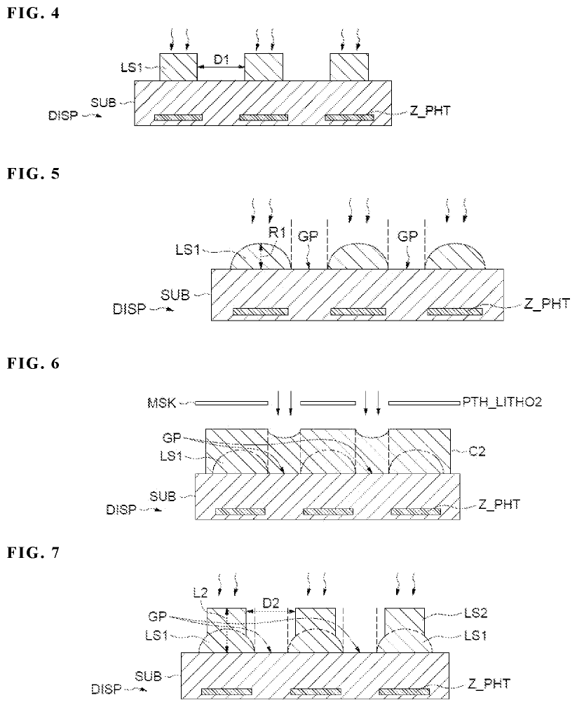

More particularly, photolithography PHT_LITHO1 is performed by using a mask MSK previously placed over the first layer of material C1. The mask MSK comprises openings to expose the surface of the first layer C1 to radiation and form the first microlens structures LS1 according to a pattern. Such a photolithography technique is known by the person skilled in the art who would know how to adjust the dimensions of the openings of the mask MSK in order to form first structures LS1 separated from one another by the first layer C1. The material of the first microlens structures LS1 and the first layer C1 is identical and can be a novolac polymer for example. FIG. 4 and FIG. 10 illustrate respectively a cross-section and view from below of a result that can be obtained following the formation 12 of first microlens structures LS1 with a cubic shape.

Advantageously, the first microlens structures LS1 are formed above photosensitive areas so as to be spaced apart from one another by a distance D1 greater than or equal to 300 nm, for example a distance D1 of between 300 nm and 600 nm. Thus, the first microlens structures LS1 have dimensions which are suitable so that the distance D1 between the first microlens structures LS1 makes it possible to prevent the formation of bridges after deformation 13 of the first microlens structures LS1.

In order to shape the first microlens structures LS1 and give them a curved shape, the method comprises the deformation 13 of the first microlens structures LS1.

The deformation 13 may be a deformation of the first microlens structures LS1 by creep, i.e. from the effect of heat. Creep is a standard technique well known to the person skilled in the art, so that the microlens structures LS1 are made liquid such that the microlens structure LS1 naturally take on a curved shape on the surface of the support substrate SUB. FIG. 5 illustrates a cross-sectional view of a result that can be obtained as a result of this deformation 13.

After the deformation 13, the first microlens structures LS1 are separated from one another by spacer regions GP. The spacer regions GP are the regions of the support substrate SUB located between the first microlens structures LS1, which are therefore not covered by the first microlens structures LS1. By adjusting the dimensions of the openings of the mask MSK during the first photolithography PHT_LITHO1 and the deformation of the first microlens structures, it is possible to determine precisely the width of the spacer regions GP between each first microlens structure LS1.

Then, the method comprises cross-linking 14 the first microlens structures LS1 by heat treatment following the deformation 13. Cross-linking 14 makes it possible to remove the solvents in each of the first microlens structures LS1 and solidify the first microlens structures LS1 so as to maintain their fixed position and stabilize them on the support substrate SUB.

The method also comprises forming 15 a second layer of material C2 on the first microlens structures LS1 and on the support substrate SUB in the spacer regions GP. The second layer C2 can be formed from photosensitive resin, identical to the resin used for the first layer C1 or from a different material such as poly(hydroxystyrene) (PHS). The resin can be for example the same as the one used for the first layer C1 and the first microlens structures LS1, i.e. MFR 400LL novolac polymer resin. FIG. 6 illustrates a cross-section of a result that can be obtained following this forming 15.

The method comprises forming 16 second microlens structures LS2 by photolithography PHT_LITO2 such that the second microlens structures LS2 extend over the first microlens structures LS1. Each second microlens structure LS2 then has an intermediate pattern of dots.

Photolithography PHT_LITHO2 is performed using a mask MSK placed previously over the second layer of material C2. Advantageously, the photolithography processes PHT_LITHO1 and PHT_LITHO2 make it possible to form the first microlens structures LS1 and the second microlens structures LS2 are performed by using the same mask MSK. The use of a single mask MSK for the two photolithography processes PHT_LITHO1 and PHT_LITHO2 makes it possible to reduce the cost of manufacturing microlenses and perform a second photolithography process PHT_LITHO2 more rapidly.

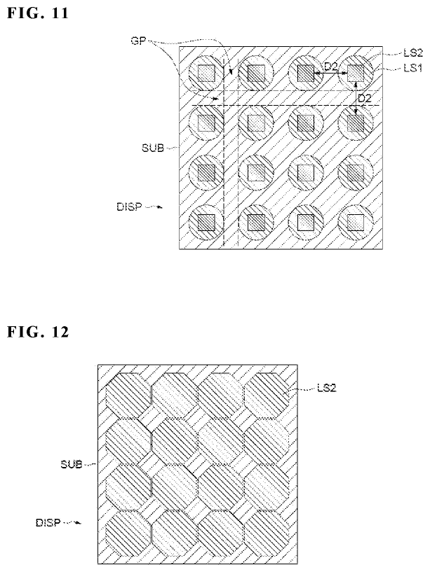

The material of the second microlens structures LS2 and the second layer C2 is identical and can be for example made of MFR 400LL resin, based on a novolac polymer. FIG. 7 and FIG. 11 illustrate respectively a cross-section and top view of a result that can be obtained following the formation 16 of second microlens structures LS2 with a cubic form.

Advantageously, the second microlens structures LS2 are formed so as to be spaced apart before deformation 17 relative to one another by a distance D2 greater than 300 nm, for example a distance D2 between 300 nm and 400 nm. The distance D2 can be equal to distance D1 corresponding to the spacing between the first microlens structures LS1.

Advantageously, the thickness of the second microlens structures is greater than 0.1 μm. The second microlens structures LS2 then have a thickness E2 which is sufficient to be better distributed in the spacer regions GP between the first microlens structures LS1 following deforming 17, described below, of second microlens structures LS2 and to make it possible to reduce or even remove the spacing between the microlenses.

Furthermore, the thickness E2 of the second microlens structures LS2 is between 400 nm and 4 μm. The method also makes it possible, after the deformation 17 of the second microlens structures LS2, to use second microlens structures LS2 for smoothing the surface of the first microlens structures LS2 that can be relatively rough. Thus, the finishing of the surface of the microlenses can be improved.

The method comprises deforming 17 the second microlens structures LS2 such that the second microlens structures LS2 have a curved form matching the curved form of the first microlens structures LS1 and extend partly into the spacer regions GAP between the first microlens structures LS1.

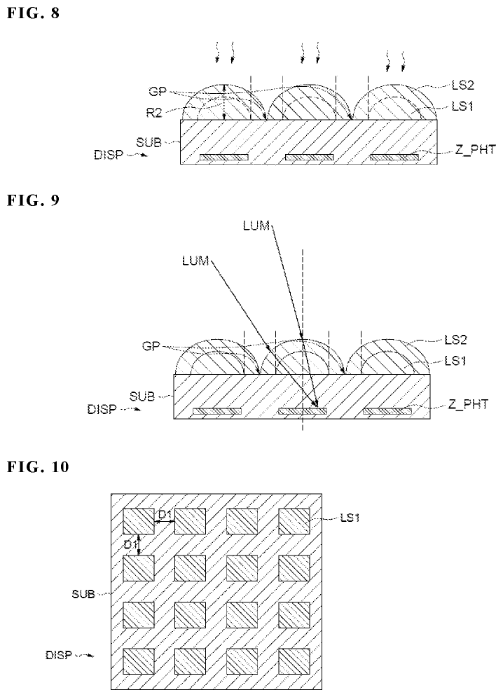

The deformation 17 can be deformation of the second microlens structures LS2 by creep, i.e. under the action of heat. The method therefore makes it possible to adjust the creep technique described above in order to allow second microlens structures LS2 to naturally take on a curved form on the surface of first microlens structures LS1. FIG. 8 illustrates a cross-section of a result that can be obtained following this deformation 17.

Advantageously, the deformation 17 of the second microlens structures LS2 comprises a diffusion plasma treatment at a suitable temperature. The temperature of the diffusion plasma treatment can be determined as a function of the nature of the material of the second microlens structures LS2 making it possible to better control the deformation 17 of the second microlens structures LS2 and obtain the desired form of microlens. The temperature of the plasma diffusion treatment is typically between 150° C. and 180° C.

In particular, the diffusion plasma is a carbon and dioxygen tetrafluoride with the chemical formula CF₄O₂. Contrary to other types of plasma, the carbon and dioxygen tetrafluoride plasma has the advantage of allowing deformation of microlens structures without the risk of damaging the photosensitive areas of the optical sensor DISP and without affecting the roughness of the microlenses.

After deformation 17, each second microlens structure LS2 has a curvature greater than or equal to a curvature of each first microlens structure LS1. For example, the radius of curvature R1 of the first microlenses LS1 can be between 20° and 40° and the radius of curvature R2 of the second microlens structures LS2 can be between 40° and 60°.

The curvature of each second microlens structure LS2 can therefore be adjusted independently of the curvature of each first mircolens structure LS1. A higher microlens curvature makes it possible to reduce the focal length of the microlens so that light can be focused on the light-sensitive area when the latter is close to the microlens.

Then, the method comprises cross-linking 18 the second microlens structures LS2 by heat treatment following the deformation 17 of the second microlens structures LS2. Cross-linking 18 makes it possible to solidify the second microlens structures LS2 in order to maintain their fixed position and to stabilize them on the support substrate SUB.

The two-step formation of microlenses by forming firstly first microlens structures then second microlens structures on the first microlens structures makes it possible to form microlenses without forming bridges, which can cause a loss of light and optical interference between the photosensitive areas of the optical sensor DISP. Consequently, the optical sensor DISP benefits from improved quantum efficiency and enhanced performance. FIG. 12 illustrates a view from above of a result that can be obtained following this deformation 17.

FIG. 9 illustrates a cross-sectional view of an optical sensor DISP made from the method described above that includes photosensitive areas Z_PHT located below each second microlens structure LS2.

The microlenses formed from the first microlens structures LS1 and second microlens structures LS2 of an optical sensor DISP do not having a spacing between them, or a very reduced spacing and make it possible to thus focus the incidental light LUM on the photosensitive area Z_PHT covered by each microlens. Preferably, the second microlens structures LS2 are spaced apart from one another, after deformation 17, by a distance of at least essentially zero. For example, in some embodiments, the second microlens structures are not spaced apart from each other after deformation 17. Consequently, such an optical sensor DISP has the advantage of increasing the amount of photons collected by the photosensitive areas Z_PHT as well as the overall quantum efficiency without a loss of light or optical interference between the photosensitive areas.

Of course, other variants and modifications of the present are possible which are apparent to the person skilled in the art. For example, the first microlens structures LS1 and the second microlens structures LS2 can be formed by different materials. Preferably, the second microlens structures LS2 are formed from a material configured to limit the reflection of light LUM on the outer surface of the second microlens structures LS2. This material can be for example of the siloxane type (cyclical or bicyclical) or PET (polyester) or acrylic, acting as an anti-reflective coating according to the external environment of the lens. In particular, the material forming the second microlens structures LS2 has a refractive index between 1.5 and 1.7. By limiting the reflection of light LUM on the outer surface of the second microlens structures LS2, a loss of photons is avoided. The quantum efficiency of the photosensitive areas is then increased.

What is claimed is:

1. A method for manufacturing an optical device on a support substrate, the method comprising:
forming first microlens structures on the support substrate using a first photolithography process such that the first microlens structures are separated from one another;
deforming the first microlens structures so as to give the first microlens structures a curved shape, wherein the first microlens structures are separated from one another by spacer regions after deformation;
forming second microlens structures substrate using a second photolithography process such that the second microlens structures extend over the first microlens structures; and
deforming the second microlens structures such that the second microlens structures have a curved form matching the curved shape of the first microlens structures and extend partly into the spacer regions between the first microlens structures.

2. The method according to claim 1, wherein, after deformation, each second microlens structure has a curvature greater than or equal to a curvature of each first microlens structure.

3. The method according to claim 1, further comprising:
cross-linking the first microlens structures by heat treatment after deforming the first microlens structures, and
cross-linking second microlens structures by heat treatment after deforming the second microlens structures.

4. The method according to claim 1, wherein the first photolithography process and the second photolithography process are performed using a same mask.

5. The method according to claim 1, wherein deforming the second microlens structures comprises performing a diffusion plasma treatment at a first temperature.

6. The method according to claim 5, wherein the diffusion plasma treatment comprises using a carbon and dioxygen tetrafluoride plasma.

7. The method according to claim 1, wherein the first microlens structures and the second microlens structures are formed by different materials.

8. The method of claim 1, wherein the first microlens structures and the second microlens structures are each formed by a novolac polymer resin.

9. The method according to claim 1, wherein the second microlens structures are formed from a material selected to limit a reflection of light from an outer surface of second microlens structures.

10. The method according to claim 1, wherein forming the second microlens structures substrate using the second photolithography process comprising forming the second microlens structures to be spaced apart from one another prior to deforming the second microlens structures.

11. The method according to claim 1, wherein the second microlens structures are not spaced apart from one another after deforming the second microlens structures.

12. An optical sensor comprising:
a support substrate;
first microlens structures with a curved shape arranged on the support substrate, wherein the first microlens structures are separated from one another by spacer regions; and
second microlens structures extending over the first microlens structures and deformed such that the second microlens structures have a curved form matching the curved shape of the first microlens structures and extend partly into the spacer regions between the first microlens structures.

13. The optical sensor according to claim 12, wherein each second microlens structure of the second microlens structures has a curvature greater than or equal to a curvature of each first microlens structure.

14. The optical sensor according to claim 12, wherein materials of the first microlens structures are different from materials of the second microlens structures.

15. The optical sensor according to claim 12, wherein the first microlens structures and the second microlens structures are made of novolac polymer resin.

16. The optical sensor according to claim 12, wherein a material of the second microlens structures is configured to limit reflection of light on an outer surface of the second microlens structures.

17. The optical sensor according to claim 16, wherein the material of the second microlens structures has an index of refraction of between 1.5 and 1.7.

18. The optical sensor according to claim 12, wherein a thickness of the second microlens structures is between 400 nm and 4 μm.

19. The optical sensor according to claim 12, wherein a thickness of the second microlens structures is greater than 0.1 μm.

20. The optical sensor according to claim 12, wherein the first microlens structures are spaced apart from one another by a distance greater than or equal to 300 nm.

21. The optical sensor according to claim 20, wherein the second microlens structures are not spaced apart from one another.

22. A method of operating an optical sensor comprising, a support substrate; first microlens structures with a curved shape arranged on the support substrate, wherein the first microlens structures are separated from one another by spacer regions; second microlens structures extending over the first microlens structures and deformed such that the second microlens structures have a curved form matching the curved shape of the first microlens structures and extend partly into the spacer regions between the first microlens structures; and photosensitive zones, each of which is disposed beneath a corresponding first microlens structure of the first microlens structure, the method comprising:
receiving light by the first microlens structures and the second microlens structures;
focusing the received light on the photosensitive zones by the first microlens structures and the second microlens structures; and
detecting the focused received light by the photosensitive zones.
